(19) United States
(12) Patent Application Publication
(10) Pub. No.: US 2014/0027904 A1
(43) Pub. Date: Jan. 30, 2014

(54) SEMICONDUCTOR DEVICE

(71) Applicant: Elpida Memory, Inc., Tokyo (JP)

(72) Inventor: Keiyo KUSANAGI, Tokyo (JP)

(21) Appl. No.: 13/945,484

(22) Filed: Jul. 18, 2013

(30) Foreign Application Priority Data
Jul. 24, 2012 (JP) 2012-163911

(51) Int. Cl. H01L 23/29; H01L 23/498

(52) U.S. Cl. CPC H01L 23/293; H01L 23/49811
USPC 257/737

(57) ABSTRACT

A semiconductor device 200 includes a wiring board 201, first bump lines 204a and 204b arranged adjacent to each other on a surface of the wiring board 201, a semiconductor chip 203 mounted on the wiring board 201 with the first bump lines 204a and 204b interposed between the semiconductor chip 203 and the wiring board 201, a sealing resin 211 filled in a gap formed between the wiring board 201 and the semiconductor chip 203, and second bump lines 205a and 205b provided between the wiring board 201 and the semiconductor chip 203 guiding the sealing resin 211 toward an area between the first bump line 204a and the first bump line 204b.

This application is based upon and claims the benefit of priority from Japanese patent application No. 2012-163911, filed on Jul. 24, 2012, the disclosure of which is incorporated herein in its entirety by reference.

### BACKGROUND OF THE INVENTION

1. Field of the Invention

The present invention relates to a semiconductor device.

2. Description of Related Art

A ball grid array (BGA) semiconductor device includes a wiring board, a semiconductor chip mounted on a first surface of the wiring board, and electrodes of balls such as solder formed on a second surface of the wiring board with a predetermined arrangement. The balls and the semiconductor chip are electrically connected to each other while the wiring board is interposed between the balls and the semiconductor chip. The semiconductor chip is sealed with a resin.

A structure using wire bonding has been known as a structure electrically connecting the balls and the semiconductor chip to each other while interposing the wiring board between the balls and the semiconductor chip.

Meanwhile, FC-BGA, in which a semiconductor chip is mounted on a wiring board by flip chip bonding, has been studied as one of structures other than the structure using wire bonding.

With the FC-BGA technology, a resin should be filled into a gap formed between a wiring board and a semiconductor chip. Therefore, if a sealing resin is filled into between bump electrodes arranged in two rows at a central region of the chip, voids may be generated between the electrodes arranged in two rows.

In order to prevent such voids from being generated, a hole for air vent may be formed in the wiring board at an area in which voids are likely to be generated.

For example, JP-A 11-97586 (Patent Literature 1) discloses a BGA type semiconductor device including wiring provided on a circuit board formed of a TAB tape and a chip mounted on the wiring. The chip is electrically connected to the wiring via bumps. A space including the chip and the wiring is sealed with a resin. A through hole releasing air (voids) is defined at a central portion of the TAB tape near a chip mounting area in which air (voids) included in the resin is likely to accumulate.

### SUMMARY

With a structure having a through hole defined in a circuit board as in Patent Literature 1, however, when the sealing of a resin is conducted with use of a sealing mold, the sealing resin may flow through the thorough hole onto a rear face of the circuit board. By this leakage of the sealing resin to the rear face of the circuit board, solder balls, which serve as external terminals, cannot be mounted satisfactorily on the circuit board. Thus, the reliability of the semiconductor device may be lowered.

Furthermore, when a structure having a through hole defined in a circuit board as in Patent Literature 1 is applied to batch molding, a cavity needs to be formed in a lower mold of sealing molds at a position corresponding to the through hole because the circuit board has the through hole defined therein.

However, if a cavity is formed at such a position, a lower mold should be prepared for each product. Therefore, the manufacturing cost may be increased.

Therefore, there has been desired a semiconductor device including a structure that can promote filling of a sealing resin without affecting the reliability or manufacturing cost of the device even if flip chip bonding is used.

According to a first aspect of the present invention, there is provided a semiconductor device comprising: a wiring board; a semiconductor chip including a plurality of bump lines arranged adjacent to each other on a surface of the semiconductor chip, the semiconductor chip being mounted on the wiring board while the plurality of bump lines are interposed between the semiconductor chip and the wiring board; a sealing resin filled in at least a gap between the wiring board and the semiconductor chip; and a guide portion provided between the wiring board and the semiconductor chip guiding the sealing resin toward an area between the adjacent bump lines.

According to a second aspect of the present invention, there is provided a semiconductor device comprising: a semiconductor chip including a plurality of bump lines arranged adjacent to each other on a surface of the semiconductor chip, the semiconductor chip being mounted on a wiring board while the plurality of bump lines are interposed between the semiconductor chip and the wiring board; and a guide portion guiding a sealing resin to be formed on the surface of the semiconductor chip toward an area between the adjacent bump lines.

According to a third aspect of the present invention, there is provided a semiconductor device comprising: a wiring substrate including an upper surface thereof; a semiconductor chip including a first surface, a plurality of first bump electrodes arranged along a first line on the first surface and a plurality of second bump electrodes arranged along a second line on the first surface, the second line being arranged in parallel with the first line and adjacent to the first line, the semiconductor chip being mounted over the upper surface of the wiring substrate so that the first and second bump electrodes interpose between the wiring substrate and the semiconductor chip; and a sealing resin filled in a gap between the wiring substrate and the semiconductor chip, wherein the wiring substrate includes a guide portion formed on the upper surface thereof, the guide portion is uneven with respect to a remaining portion of the upper surface, and the guide portion is extended from an area between the first and second lines toward a peripheral edge of the wiring substrate.

### Advantageous Effects of the Invention

According to the present invention, there can be provided a semiconductor device including a structure that can promote filling of a sealing resin without affecting the reliability or manufacturing cost of the device even if flip chip bonding is used.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional view showing a semiconductor device according to a first embodiment of the present invention.

FIG. 2 is a bottom view of a semiconductor chip of the semiconductor device shown in FIG. 1, as viewed along arrow 2 of FIG. 1.

FIG. 3 is a cross-sectional view taken along line A-A′ of FIG. 2.

FIG. 4A is a cross-sectional view showing a process of assembling a semiconductor device according to the first embodiment of the present invention.

FIG. 4B is a cross-sectional view showing a process of assembling a semiconductor device according to the first embodiment of the present invention.

FIG. 4C is a cross-sectional view showing a process of assembling a semiconductor device according to the first embodiment of the present invention.

FIG. 4D is a cross-sectional view showing a process of assembling a semiconductor device according to the first embodiment of the present invention.

FIG. 4E is a cross-sectional view showing a process of assembling a semiconductor device according to the first embodiment of the present invention.

FIG. 5A is a top view showing a process of assembling a semiconductor device according to the first embodiment of the present invention.

FIG. 5B is a top view showing a process of assembling a semiconductor device according to the first embodiment of the present invention.

FIG. 6 is a cross-sectional view showing a process of assembling a semiconductor device according to the first embodiment of the present invention.

FIG. 7 is a cross-sectional view showing a process of assembling a semiconductor device according to the first embodiment of the present invention.

FIG. 8 is a cross-sectional view showing a process of assembling a semiconductor device according to the first embodiment of the present invention.

FIG. 9 is a bottom view showing a semiconductor device according to a second embodiment of the present invention, in which components other than a semiconductor chip are omitted from the illustration.

FIG. 10 is a cross-sectional view showing a semiconductor device according to a third embodiment of the present invention.

FIG. 11 is a bottom view of a semiconductor chip of the semiconductor device shown in FIG. 10, as viewed along arrow 11 of FIG. 10.

FIG. 12A is a cross-sectional view showing a process of assembling a semiconductor device according to the third embodiment of the present invention.

FIG. 12B is a cross-sectional view showing a process of assembling a semiconductor device according to the third embodiment of the present invention.

FIG. 13 is a plan view showing a semiconductor device according to a fourth embodiment of the present invention, in which part of a sealing resin 211 and a semiconductor chip is cut away.

FIG. 14 is a cross-sectional view taken along line B-B′ of FIG. 13.

FIG. 15 is a plan view showing a semiconductor device according to a fifth embodiment of the present invention, in which part of a sealing resin 211 and a semiconductor chip is cut away.

FIG. 16 is a cross-sectional view taken along line C-C′ of FIG. 15.

FIG. 17 is a bottom view showing a semiconductor device according to a sixth embodiment of the present invention, in which components other than a semiconductor chip are omitted from the illustration.

FIG. 18 is a bottom view showing a semiconductor device according to a seventh embodiment of the present invention, in which components other than a semiconductor chip are omitted from the illustration.

FIG. 19 is a bottom view showing a semiconductor device according to an eighth embodiment of the present invention, in which components other than a semiconductor chip are omitted from the illustration.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

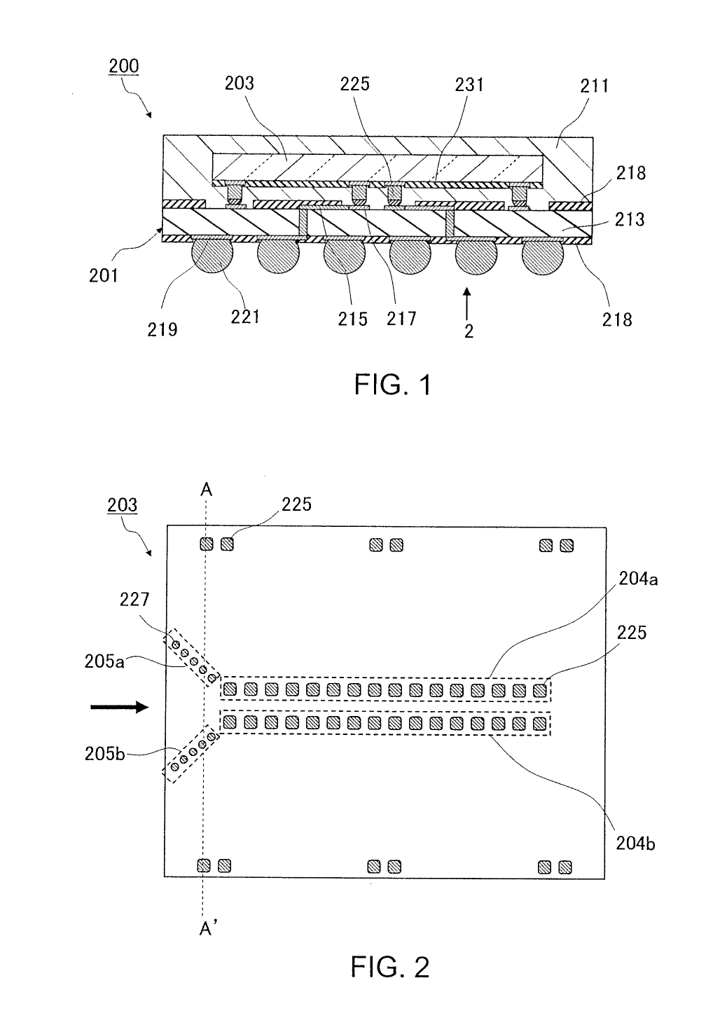

First, an outlined structure of a semiconductor device 200 according to a first embodiment of the present invention will be described with reference to FIGS. 1 and 2.

In the first embodiment, a semiconductor memory including a memory chip is illustrated as the semiconductor device 200.

As shown in FIG. 1, the semiconductor device 200 includes a wiring board 201, first bump lines 204a and 204b as a plurality of bump lines (first and second lines) arranged adjacent to each other on a surface of the wiring board 201, a semiconductor chip 203 mounted on the wiring board 201 via the first bump lines 204a and 204b, a sealing resin 211 filled in a gap between the wiring board 201 and the semiconductor chip 203, and second bump lines 205a and 205b provided between the wiring board 201 and the semiconductor chip 203. The second bump lines 205a and 205b serve as guide portions guiding the sealing resin 211 toward an area between the first bump line 204a and the first bump line 204b.

Now the details of components of the semiconductor device 200 will be described with reference to FIGS. 1 to 3.

The wiring board 201 includes a substrate 213, which has a rectangular shape in a plan view, for example, wiring patterns 215 formed on both surfaces of the substrate 213, and insulation films 218 covering part of the wiring patterns 215. For example, the substrate 213 is made of glass epoxy having a thickness of 0.2 mm. The wiring patterns 215 are made of a material such as Cu. The insulation films 218 are made of a solder resist or the like.

A plurality of connection pads 217 are formed on a surface of the substrate 213, on which the semiconductor chip 203 is mounted. Those connection pads 217 are located at portions of the wiring pattern 215 exposed from the insulation film 218. A plurality of lands 219 are formed on another surface of the substrate 213. Those lands 219 are located at portions of the wiring pattern 215 exposed from the insulation film 218.

Each of the connection pads 217 is electrically connected to the corresponding land 219 by the wiring patterns 215.

Furthermore, solder balls 221 are mounted as external terminals on the lands 219.

Meanwhile, the semiconductor chip 203 is mounted on the first surface of the substrate 213 by a flip chip mounting process.

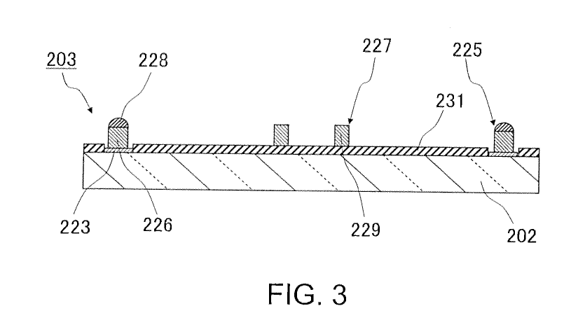

As shown in FIG. 3, the semiconductor chip 203 includes a rectangular platelike silicon substrate 202, some circuits (not shown), such as memory circuits, formed on a surface of the silicon substrate 202, and a plurality of electrode pads 223 formed on the surface (first surface 202a) of the silicon substrate 202. The electrode pads 223 are used for input/output of the circuits.

For example, the electrode pads 223 are arranged in two rows at a central area of the semiconductor chip 203 and also arranged at a peripheral area of the semiconductor chip 203 along the rows of the electrode pads 223 at the central area of the semiconductor chip 203.

Furthermore, a passivation film 231 is formed on the surface of the semiconductor chip 203 in an area other than the electrode pads 223, so that the circuit formation surface is protected by the passivation film 231.

Moreover, first bumps 225, such as function bumps, are formed on the electrode pads 223. As shown in FIG. 3, each of the first bumps 225 includes a pillar 226 of Cu and a solder layer 228 formed on the pillar 226. The pillar 226 is roughly in the form of a quadrangular prism. A reflow process is performed on solder at a certain temperature, and the molten solder is swelled at a central portion thereof by surface tensions. Thus, the solder layer 228 is formed in the form of an arc on the pillar 226.

As described above, some of the electrode pads 223 are arranged in two rows at the central area of the semiconductor chip 203. Thus, the first bumps 225 formed on those electrode pads 223 constitute the first bump line 204a and the first bump line 204b, which are located adjacent to each other. In this embodiment, first bump line 204b is arranged in parallel with the first bump line 204a and a plurality of first bump electrodes arranged along a first line on the first surface and a plurality of second bump electrodes arranged along a second line on the first surface.

Furthermore, as shown in FIG. 2, a plurality of second bumps 227 (filling promotion portion) are formed on the surface of the semiconductor chip 203 (the surface on which the first bump 225 are formed) in the semiconductor device 200. The intervals between the second bumps 227 gradually decrease from one side of the wiring board 201 in a filling direction of the sealing resin 211, which will be described below, toward an area between the adjacent two bump lines (an area between the first bump line 204a and the first bump line 204b). The second bumps 227 are arranged in two rows, which constitute a second bump line 205a and a second bump line 205b.

As shown in FIG. 3, each of the second bumps 227 includes a pillar 229 of Cu. The pillar 229 is in the form of a cylinder in consideration of the fluidity of the sealing resin 211.

The second bumps 227 do not necessarily need to be electrically connected to the wiring board 201. Therefore, no solder layer may be formed on the pillar 229 of each of the second bumps 227, unlike the first bumps 225. Since the second bumps 227 are dummy bumps, they are formed on the passivation film 231, which is formed on the semiconductor chip 203, in the example shown in FIG. 3.

Since the second bumps 227 do not require an electrode pad, they can be arranged at any desired positions without changing the layout of the circuits of the semiconductor chip 203 or the electrode pads 223. Furthermore, since the semiconductor chip 203 is mounted on the wiring board 201 by a flip chip mounting process, the first bumps 225 of the semiconductor chip 203 are joined to the connection pads 217 of the wiring board 201 via the solder layers 228.

Furthermore, the sealing resin 211 of a thermosetting epoxy resin or the like is provided on the surface of the wiring board 201. A gap formed between the wiring board 201 and the semiconductor chip 203 is filled with the sealing resin 211, and a rear face of the semiconductor chip 203 is covered with the sealing resin 211.

As described above, the second bump lines 205a and 205b (filling promotion portion) are provided between the wiring board 201 and the semiconductor chip 203 so that the intervals between those second bump lines 205a and 205b gradually decrease from one side of the wiring board 201 toward an area between the adjacent first bump lines 204a and 204b. Therefore, voids can be prevented from being generated in the sealing resin 211 filling at least the gap between the wiring board 201 and the semiconductor chip 203.

With the above structure, no through hole needs to be formed in the wiring board 201. Therefore, the sealing resin 211 does not flow onto the lands 219 formed on the rear face of the wiring board 201. Thus, the reliability of the semiconductor device 200 can be improved.

Furthermore, the second bumps 227 including the second bump lines 205a and 205b are formed on the passivation film 231. Thus, no electrode pads need to be formed for the second bumps 227. Therefore, the second bump lines 205a and 205b can be formed without increasing the size of the semiconductor chip 203.

In the above example, the second bumps 227 are formed on the passivation film 231. Nevertheless, the second bumps 227 may be formed on electrode pads and used as supplementary power source terminals or GND terminals.

The above discussion has focused on the details of components of the semiconductor device 200.

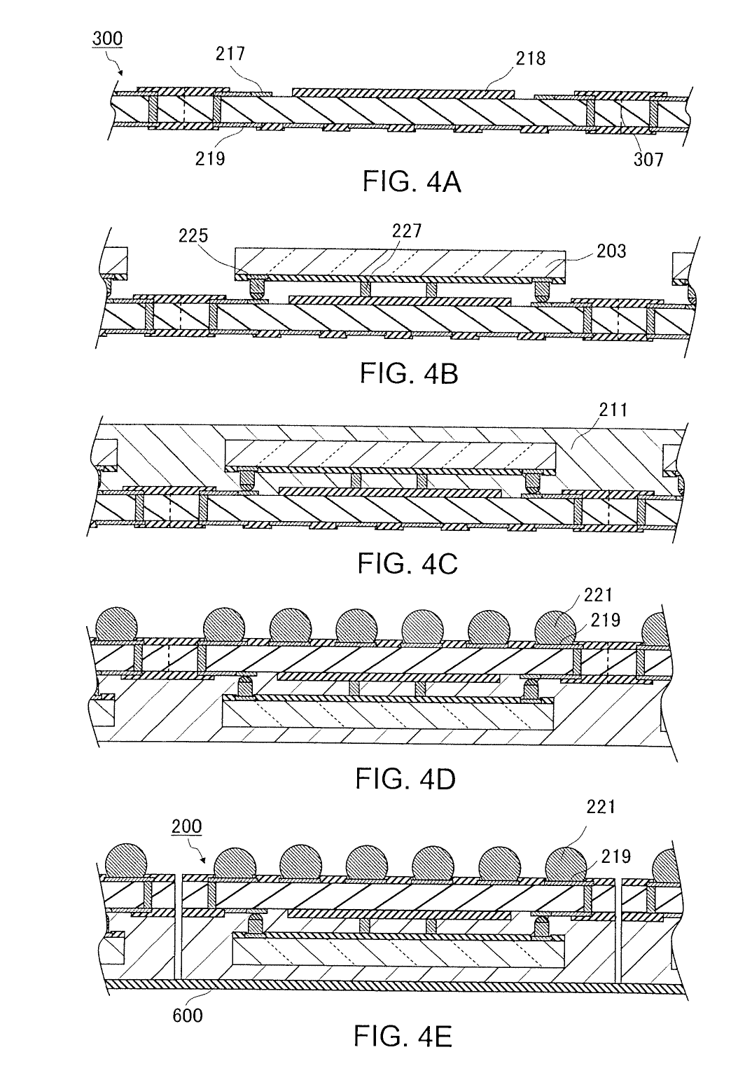

Now a process of assembling the semiconductor device 200 will be described with reference to FIGS. 4A to 8.

First, a base wiring substrate 300 as shown in FIG. 4A is prepared.

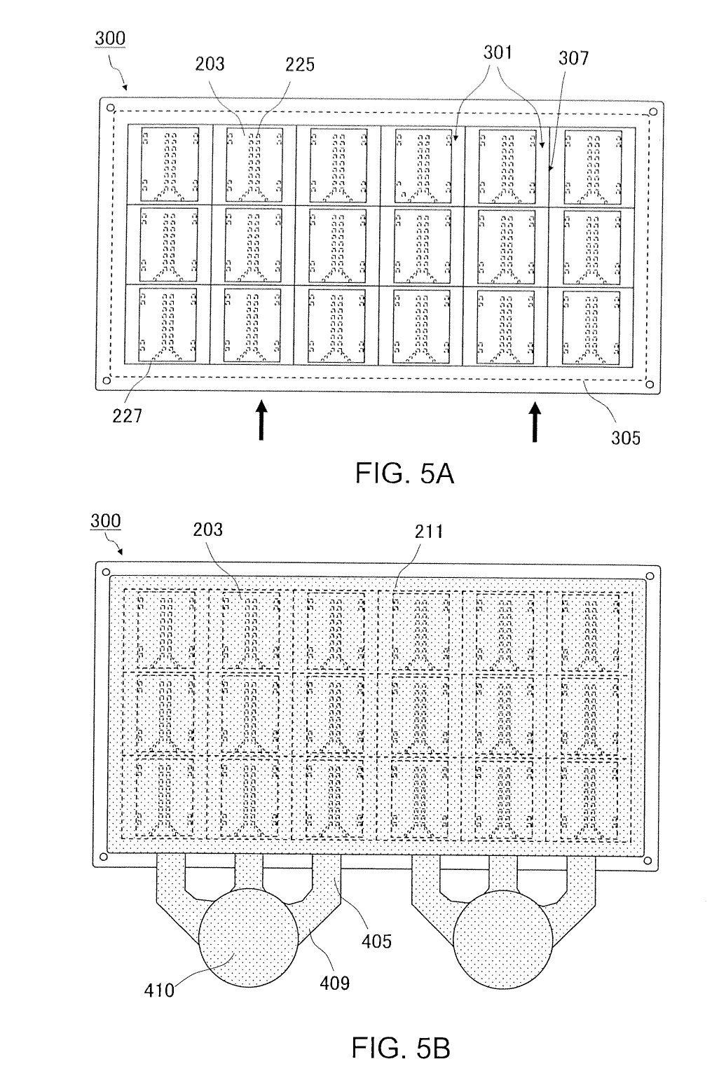

The base wiring substrate 300 includes a plurality of product formation portions 301 arranged in a matrix form. Each of the product formation portions 301 corresponds to one wiring board 201. Dicing lines 307 are formed between the product formation portions 301. Those dicing lines 307 correspond to cutting planes used to separate the product formation portions 301 from each other (see FIG. 5A).

Then, as shown in FIGS. 4B and 5A, a semiconductor chip 203 is mounted on each of the product formation portions 301 by a flip chip mounting process.

Specifically, a rear face of the semiconductor chip 203 is attracted to a bonding tool of a flip chip bonder (not shown) by suction. A load is applied to the semiconductor chip 203 upon heating at about 240° C. so as to join the first bumps 225 of the semiconductor chip to the connection pads 217 of the wiring board 201. Thus, the semiconductor chip 203 is mounted on the wiring board 201.

In other words, the semiconductor chip 203 includes the first bumps 225 and the second bumps 227 formed thereon as described above. The first bumps 225 are joined to the connection pads 217 on the wiring board 201 with the solder layers 228. Thus, the semiconductor chip 203 is mounted on the wiring board 201.

The second bumps 227 serve as dummy bumps promoting the filling of the sealing resin 211 as described above. Therefore, the second bumps 227 may not joined to the connection pads 217 of the wiring board 201.

As shown in FIG. 5A, the semiconductor chip 203 is mounted on each of the product formation portions 301 of the base wiring substrate 300 by a flip chip mounting process such that an edge of the semiconductor chip 203 near which the second bumps 227 have been formed is opposed to a direction in which the sealing resin 211 is being filled (as indicated by black arrows of FIG. 5A). After completion of flip chip bonding, the wiring board is transferred to a molding apparatus 400.

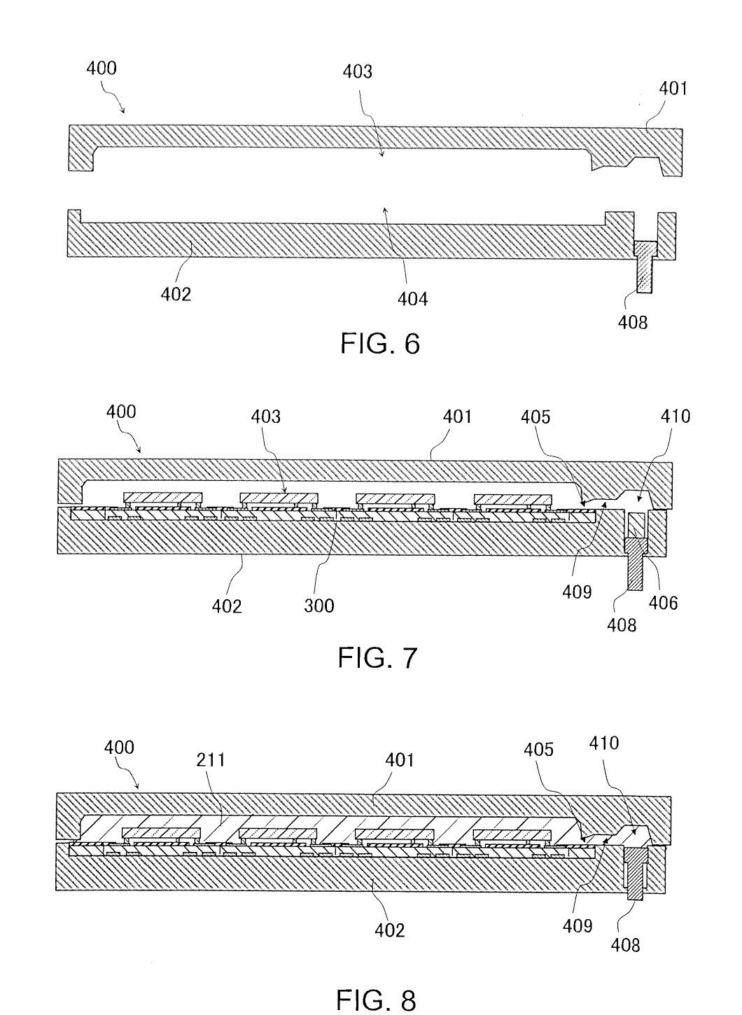

The molding apparatus 400 has a molding tool including an upper mold 401 and a lower mold 402 as illustrated in FIG. 6. The upper mold 401 has a cavity 403 defined therein, and the lower mold 402 has a recessed portion 404 formed therein. The base wiring substrate 300 is mounted onto a bottom of the recessed portion 404.

After completion of flip chip bonding, the base wiring substrate 300 is set into the recessed portion 404 of the lower mold 402.

Then the upper mold 401 and the lower mold 402 are closed into a state illustrated in FIG. 7. Thus, a certain volume of a cavity 403 and gate portions 405 are formed above the base wiring substrate 300. In the present embodiment, the molding apparatus has a mold array package (MAP) configuration. Therefore, the cavity 403 is so large in size that a plurality of product formation portions 301 are collectively received in the cavity.

Subsequently, a resin tablet 406 (see FIG. 7) is supplied into a pot of the lower mold 402. Then the resin tablet 406 is heated and melted therein.

Thereafter, as shown in FIG. 8, the molten sealing resin 211 is injected from the gate portions 405 into the cavity 403 by a plunger 408 so that the cavity 403 is filled with the sealing resin 211.

In the first embodiment, the second bump lines 205a and 205b are provided between the wiring board 201 and the semiconductor chip 203 so that the intervals between those second bump lines 205a and 205b gradually decrease from one side of the semiconductor chip 203 that is opposed to the direction in which the sealing resin 211 is filled, toward an area between the adjacent two bump lines (the first bump line 204a and the first bump line 204b).

Therefore, the sealing resin 211 being filled between the wiring board 201 and the semiconductor chip 203 is guided by the second bump lines 205a and 205b and thus filled preferentially between the first bump line 204a and the first bump line 204b. Accordingly, voids can be prevented from being generated in the area between the first bump lines 204a and 204b. Thus, the sealing resin 211 can be filled satisfactorily.

Additionally, the filling of the sealing resin 211 can be promoted without formation of a through hole in the wiring board 201. Therefore, no sealing resin 211 flows through such a through hole onto a rear face of the wiring board 201. As a result, the lands 219 are not covered with the sealing resin 211, and the solder balls 221 can satisfactorily be mounted on the lands 219. Thus, the reliability of the semiconductor device 200 can be improved.

Since no through hole is formed in the wiring board 201, it is not necessary to form a cavity corresponding to such a through hole in the lower mold 402 of the molding apparatus 400. Therefore, the lower mold 402 can be used in common to different kinds of wiring boards. Accordingly, the cost of assembling the semiconductor device 200 can be reduced.

After the sealing resin 211 has been filled in the cavity 403, it is cured at a certain temperature, e.g., 180° C., and thus hardened.

Then the upper mold 401 and the lower mold 402 are separated from the base wiring substrate 300, which is picked up and subjected to a reflow process at a certain temperature, e.g., 240° C. Thus, the sealing resin 211 is completely hardened so that a sealing area 305 of the base wiring substrate 300 (see FIG. 5A) is covered collectively with the sealing resin 211 as shown in FIGS. 4C and 5B. Thereafter, the gate portions 405, runner portions 409, and cull portions 410 connected to the sealing resin 211 as illustrated in FIGS. 5B and 8 are removed.

Next, as shown in FIG. 4D, solder balls 221 are mounted on the lands 219 of the wiring board 201 to form external terminals.

Specifically, for example, a suction mechanism (not shown) having a plurality of suction holes is aligned with the arrangement of the lands 219 on the wiring board 201, and the solder balls 221 are held by the suction holes. The solder balls 221 being held are mounted collectively on the lands 219 of the wiring board 201 with a flux.

After the solder balls 221 have been mounted on all of the product formation portions 301, the wiring boards 201 are subjected to a reflow process to fix the solder balls 221 on the product portions 301.

Subsequently, the base wiring substrate 300 including the solder balls 221 mounted thereon is mounted on a substrate dicing apparatus (not shown).

After the base wiring substrate 300 has been mounted on the substrate dicing apparatus, as shown in FIG. 4E, the base wiring substrate 300 is cut along the dicing lines 307 and separated into the product formation portions 301. Specifically, a dicing tape 600 is attached to the sealing resin 211 on the base wiring substrate 300 via an adhesive layer (not shown) so that the wiring board 201 is supported by the dicing tape 600. Thereafter, the base wiring substrate 300 is cut longitudinally and latitudinally along the dicing lines 307 by a dicing blade of a dicing apparatus (not shown) so as to separate the product formation portions 301 from each other. After the product formation portions 301 have been cut and separated from each other, individual product formation portions 301 are picked up from the dicing tape 600. Thus, semiconductor devices 200 as illustrated in FIG. 1 are obtained.

In the above manner, the semiconductor device 200 is assembled.

In this manner, according to the first embodiment, the semiconductor device 200 includes the wiring board 201, the first bump lines 204a and 204b as a plurality of bump lines arranged adjacent to each other, the semiconductor chip 203 mounted on the wiring board 201 with the first bump lines 204a and 204b interposed between the semiconductor chip 203 and the wiring board 201, the sealing resin 211 filled in the gap formed between the wiring board 201 and the semiconductor chip 203, and the second bump lines 205a and 205b as guide portions provided between the wiring board 201 and the semiconductor chip 203 guiding the sealing resin 211 toward the area between the first bump line 204a and the first bump line 204b.

Therefore, voids can be prevented from being generated in the area between the first bump lines 204a and 204b.

Furthermore, according to the first embodiment, no through hole needs to be formed in the wiring board 201. Therefore, the sealing resin 211 does not flow through such a through hole onto the rear face of the wiring board 201. Accordingly, the reliability of the semiconductor device can be improved.

Moreover, since no through hole is formed in the wiring board 201, it is not necessary to form a cavity corresponding to such a through hole in the lower mold 402 of the molding apparatus 400. Therefore, the lower mold 402 can be used in common to different kinds of wiring boards. Accordingly, the cost assembling the semiconductor device 200 can be reduced.

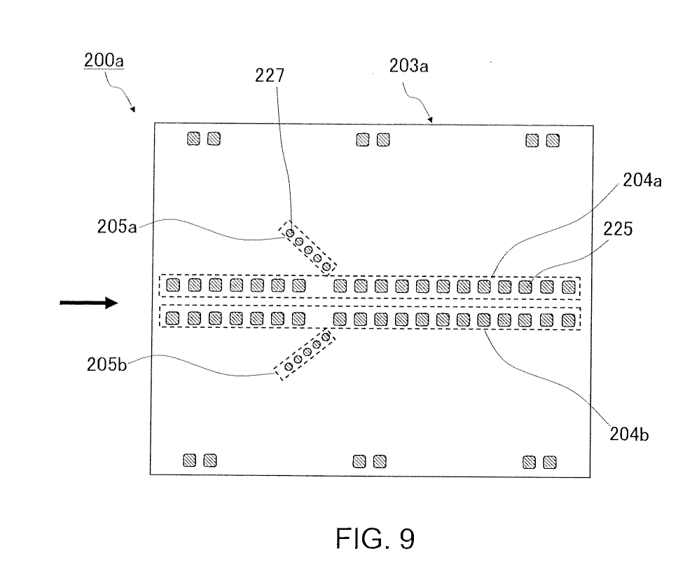

Next, a second embodiment of the present invention will be described with reference to FIG. 9.

In the second embodiment, the second bump lines 205a and 205b of the first embodiment are provided near the center of the chip, where voids are the most likely to be generated between ends of the first bump lines 204a and 204b, rather than near the ends of the first bump lines 204a and 204b.

In the second embodiment, components having the same functions as those in the first embodiment are denoted by the same reference numerals. Thus, the following description focuses on differences between the second embodiment and the first embodiment.

As shown in FIG. 9, a semiconductor device 200a according to the second embodiment includes a semiconductor chip 203a including first bump lines 204a and 204b arranged in two rows and second bump lines 205a and 205b arranged near a central portion of the semiconductor chip 203a between ends of the first bump lines 204a and 204b.

In this manner, when the first bump lines 204a and 204b extend to the vicinity of edges of the semiconductor chip 203a, a plurality of second bump lines 205a and 205b may be provided so that the intervals between those second bump lines 205a and 205b gradually decrease from one side of the semiconductor chip 203 that is opposed to a direction in which the sealing resin 211 is filled, toward the area near the center of the semiconductor chip 203a between the first bump lines 204a and 204b. Thus, the sealing resin can preferentially be filled into the area near the center of the semiconductor chip 203a between the first bump lines 204a and 204b, where voids are the most likely to be generated.

In this case, the sealing resin 211 can satisfactorily be filled into between the two bump lines by removing some first bumps 225 from locations close to the second bump lines 205a and 205b.

The structure of the semiconductor device 200a other than those bump lines is the same as that of the semiconductor device 200 of the first embodiment. Therefore, the details of the structure of the semiconductor device 200a are omitted herein.

In this manner, according to the second embodiment, the semiconductor device 200a includes the wiring board 201, the first bump lines 204a and 204b as a plurality of bump lines arranged adjacent to each other, the semiconductor chip 203a mounted on the wiring board 201 with the first bump lines 204a and 204b interposed between the semiconductor chip 203a and the wiring board 201, the sealing resin 211 filled in the gap formed between the wiring board 201 and the semiconductor chip 203a, and the second bump lines 205a and 205b as guide portions provided between the wiring board 201 and the semiconductor chip 203a guiding the sealing resin 211 toward the area between the first bump line 204a and the first bump line 204b.

Accordingly, the second embodiment exhibits the same advantageous effects as the first embodiment.

Furthermore, according to the second embodiment, the second bump lines 205a and 205b are provided near the central area of the semiconductor chip 203a between the ends of the first bump lines 204a and 204b arranged in two rows.

Accordingly, the present invention can be applied even if the first bump lines 204a and 204b extend to the vicinity of the edges of the semiconductor chip 203a.

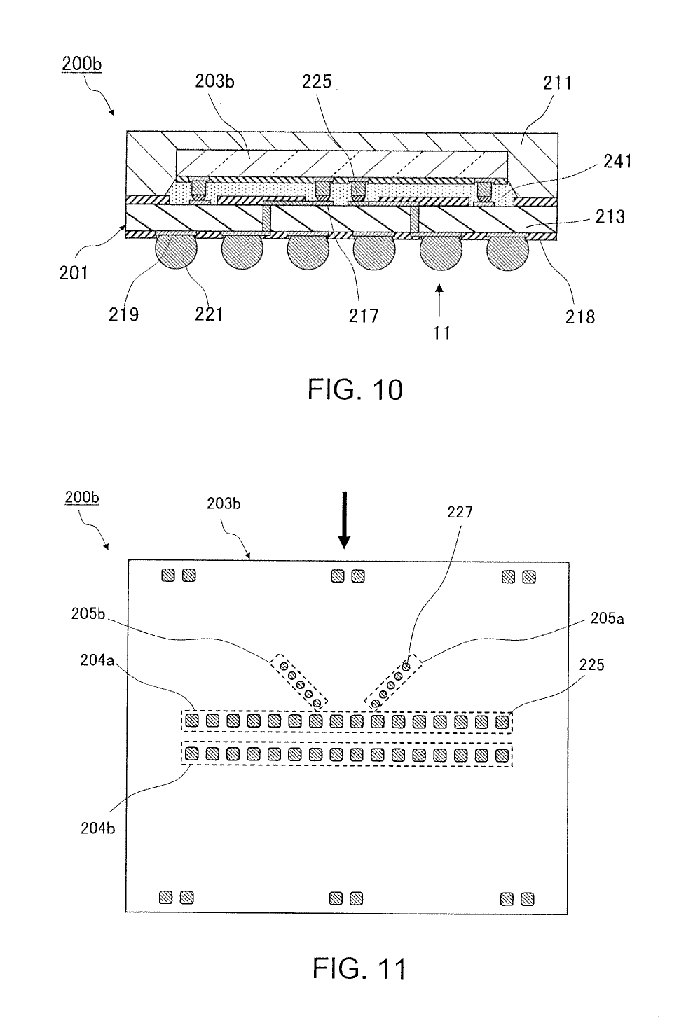

Next, a third embodiment of the present invention will be described with reference to FIGS. 10 to 12.

In the third embodiment, an underfill material 503 is filled between the wiring board 201 and the semiconductor chip 203 of the first embodiment to form an underfill portion 241.

Furthermore, the second bump lines 205a and 205b are oriented in a direction crossing a direction in which the first bump lines 204a and 204b extend (in this example, in a direction perpendicular to the direction in which the first bump lines 204a and 204b extend).

In the third embodiment, components having the same functions as those in the first embodiment are denoted by the same reference numerals. Thus, the following description focuses on differences between the third embodiment and the first embodiment.

First, an outlined structure of a semiconductor device 200b according to a third embodiment of the present invention will be described with reference to FIGS. 10 and 11.

In the semiconductor device 200b according to the third embodiment, as shown in FIG. 10, an underfill material 503, which will be described later, is filled between the wiring board 201 and the semiconductor chip 203b, so that an underfill portion 241 is formed in the semiconductor device 200b.

Furthermore, as shown in FIG. 11, the second bump lines 205a and 205b are provided so that the intervals between those second bump lines 205a and 205b gradually decrease from the vicinity of an edge of the semiconductor chip 203b in a direction perpendicular to the direction in which the first bump lines 204a and 204b extend, toward an area near the center of the semiconductor chip 203b that is located between the first bump lines 204a and 204b. This is for the purpose of filling the underfill material 503 from a long side of the roughly rectangular semiconductor chip 203b along the direction perpendicular to the direction in which the first bump lines 204a and 204b extend, which will be described later.

In this manner, the underfill material 503 may be filled between the wiring board 201 and the semiconductor chip 203b. Furthermore, the second bump lines 205a and 205b may not necessarily be arranged in parallel to the direction in which the first bump lines 204a and 204b extend.

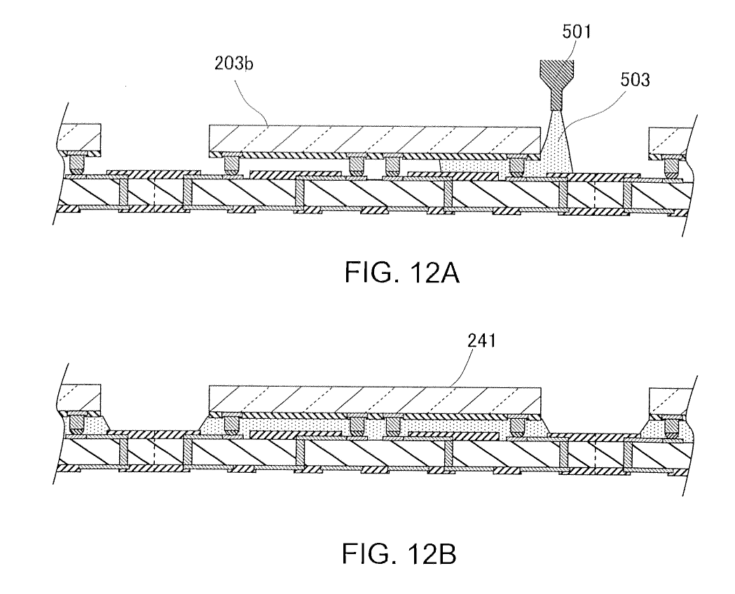

Now a process of assembling the semiconductor device 200b will be described with reference to FIGS. 12A and 12B.

First, as with the first embodiment, a base wiring substrate 300 is prepared, and a semiconductor chip 203b is mounted on each of product formation portions 301 by a flip chip mounting process.

After the flip chip mounting process, as shown in FIG. 12A, an underfill material 503 is filled between the wiring board 201 and the semiconductor chip 203b.

Specifically, as shown in FIG. 12A, an underfill material 503 is supplied from a location near the long side of the semiconductor chip 203b mounted on the product formation portion 301 in a direction indicated by an arrow of FIG. 11 with use of a dispenser 501 of a coating apparatus (not shown). Thus, the supplied underfill material 503 is filled into a gap formed between the wiring board 201 and the semiconductor chip 203b by a capillary phenomenon.

As described above, the second bump lines 205a and 205b are provided so that the intervals between those second bump lines 205a and 205b gradually decrease from the vicinity of the edge of the semiconductor chip 203b in the direction perpendicular to the direction in which the first bump lines 204a and 204b extend, toward the area near the center of the semiconductor chip 203b that is located between the first bump lines 204a and 204b. Therefore, the underfill material 503 can preferentially be filled into the area near the center of the chip, where voids are the most likely to be generated between the first bump lines 204a and 204b.

After the underfill material 503 has been filled, it is cured at a certain temperature, e.g., about 150° C. Thus, the underfill material 503 is hardened, so that the underfill portion 241 is formed as shown in FIG. 12B.

Thereafter, as with the first embodiment, the forming of the sealing resin 211, the mounting of the solder balls 221, and the cutting of the base wiring substrate 300 are conducted. The individual product formation portions 301 that have been cut and separated are picked up. Thus, semiconductor devices 200b are obtained.

In this manner, according to the third embodiment, the semiconductor device 200b includes the wiring board 201, the first bump lines 204a and 204b as a plurality of bump lines arranged adjacent to each other, the semiconductor chip 203b mounted on the wiring board 201 with the first bump lines 204a and 204b interposed between the semiconductor chip 203b and the wiring board 201, the sealing resin 211 filled in the gap formed between the wiring board 201 and the semiconductor chip 203b, and the second bump lines 205a and 205b as guide portions provided between the wiring board 201 and the semiconductor chip 203b guiding the sealing resin 211 toward the area between the first bump line 204a and the first bump line 204b.

Accordingly, the third embodiment exhibits the same advantageous effects as the first embodiment.

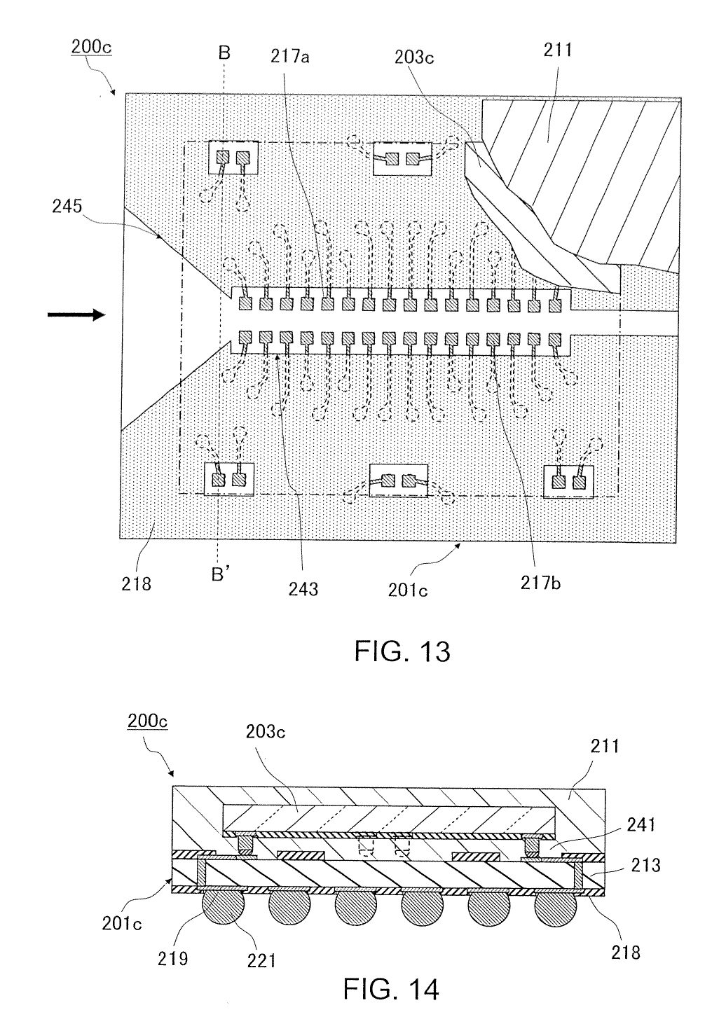

Next, a fourth embodiment of the present invention will be described with reference to FIGS. 13 and 14.

In the fourth embodiment, part of the insulation film 218 is removed to form a concave tapered opening portion 245 as a filling promotion portion, instead of bump lines.

In the fourth embodiment, components having the same functions as those in the first embodiment are denoted by the same reference numerals. Thus, the following description focuses on differences between the fourth embodiment and the first embodiment.

As shown in FIGS. 13 and 14, in a semiconductor device 200c according to the fourth embodiment, a surface of a wiring board 201c is covered with the insulation film 218. However, no insulation film 218 is formed around the connection pads 217a and 217b, so that a recessed pad opening portion 243 is formed around the connection pads 217a and 217b.

The semiconductor device 200c has a concave tapered opening portion 245 produced by removing a part of the insulation film 218. In other words, concave tapered opening portion 245 is uneven with respect to a remaining portion of the upper surface of the wiring board 201c. The concave tapered opening portion 245 is smaller in thickness than the remaining portion of the upper surface of the wiring board 201c. The tapered opening portion 245 has a width that gradually decreases from one side of the wiring board 201c (peripheral edge of the wiring board 201c) that is opposed to a direction in which the sealing resin 211 is filled, toward the connection pads 217a and 217b corresponding to the first bump lines 204a and 204b. The tapered opening portion 245 communicates with the pad opening portion 243.

Thus, the filling promotion portion according to the present invention is not limited to a convex shape such as a bump as long as it can guide the sealing resin 211 into between the first bump lines 204a and 204b. The filling promotion portion may have a concave shape formed by patterning the insulation film 218.

With this configuration, the fourth embodiment exhibits the same advantageous effects as the first embodiment. Furthermore, since a solder resist film is removed toward the area between the two bump lines, it is possible to widen a passage between the wiring board 201c and the semiconductor chip 203c for the sealing resin 211 being filled into the area between the first bump lines 204a and 204b.

The tapered opening portion 245 can be formed by removing part of the insulation film 218 from an area connecting to an area between the connection pads 217a and 217b when the pad opening portion 243 is formed by removing the insulation film 218 on and around the connection pads 217a and 217b.

Therefore, the filling promotion portion can be formed without any additional processes.

Thus, according to the fourth embodiment, the semiconductor device 200c includes the wiring board 201c, the first bump lines 204a and 204b as a plurality of bump lines arranged adjacent to each other, the semiconductor chip 203c mounted on the wiring board 201c with the first bump lines 204a and 204b interposed between the semiconductor chip 203c and the wiring board 201c, the sealing resin 211 filled in a gap formed between the wiring board 201c and the semiconductor chip 203c, and the tapered opening portion 245 as a guide portion provided between the wiring board 201c and the semiconductor chip 203c guiding the sealing resin 211 toward between the first bump line 204a and the first bump line 204b.

Accordingly, the fourth embodiment exhibits the same advantageous effects as the first embodiment.

Furthermore, according to the fourth embodiment, the semiconductor device 200c includes the tapered opening portion 245 produced by removing the insulation film 218 from an area connecting to an area between the connection pads 217a and 217b.

Accordingly, it is possible to widen a passage between the wiring board 201c and the semiconductor chip 203c for the sealing resin 211 to be filled into between the first bump lines 204a and 204b, as compared to the first embodiment.

Moreover, according to the fourth embodiment, the tapered opening portion 245 can be formed by removing part of the insulation film 218 from an area connecting to an area between the connection pads 217a and 217b when the pad opening portion 243 is formed by removing the insulation film 218 on and around the connection pads 217a and 217b.

Therefore, a filling promotion portion can be formed without any additional processes.

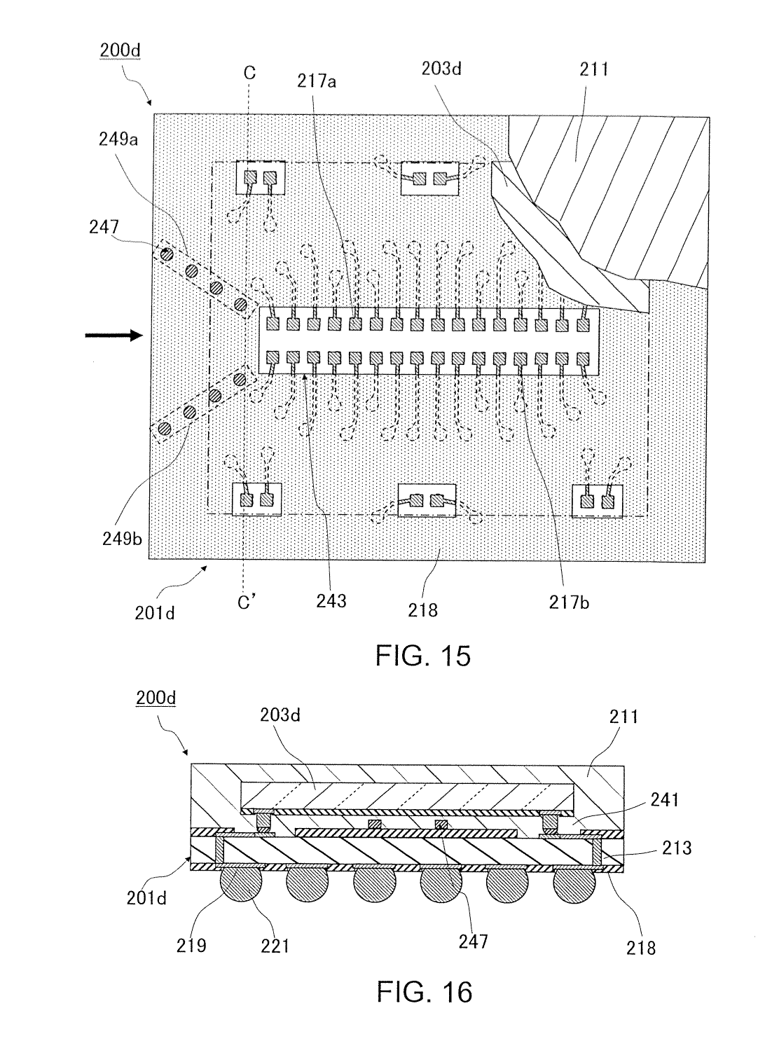

Next, a fifth embodiment of the present invention will be described with reference to FIGS. 15 and 16.

In the fifth embodiment, a filling promotion portion is provided by forming guide protrusions 247 on the insulation film 218, rather than by removing the insulation film 218 in the fourth embodiment. Those guide protrusions 247 constitute guide protrusion lines 249a and 249b.

In the fifth embodiment, components having the same functions as those in the fourth embodiment are denoted by the same reference numerals. Thus, the following description focuses on differences between the fifth embodiment and the fourth embodiment.

As shown in FIGS. 15 and 16, a semiconductor device 200d according to the fifth embodiment includes a plurality of guide protrusions 247 formed on the insulation film 218 of a wiring board 201d.

Those guide protrusions 247 constitute the guide protrusion lines 249a and 249b, which are arranged on the insulation film 218 so that the intervals between the guide protrusion lines 249a and 249b gradually decrease from one side of the wiring board 201d that is opposed to a direction in which the sealing resin is filled, toward an area between the two bump lines (more accurately, between the pads corresponding to the bump lines).

The material of the guide protrusions 247 is not limited to a specific one as long as the guide protrusions 247 can guide the sealing resin 211 into an area between the first bump lines 204a and 204b.

Thus, the filling promotion portion can be formed by providing protrusions on the insulation film 218, rather than by forming a recessed portion through removal of the insulation film 218.

In this manner, according to the fifth embodiment, the semiconductor device 200d includes the wiring board 201d, the first bump lines 204a and 204b as a plurality of bump lines arranged adjacent to each other, the semiconductor chip 203d mounted on the wiring board 201d with the first bump lines 204a and 204b interposed between the semiconductor chip 203d and the wiring board 201d, the sealing resin 211 filled in the gap formed between the wiring board 201d and the semiconductor chip 203d, and the guide protrusion lines 249a and 249b as guide portions provided between the wiring board 201d and the semiconductor chip 203d guiding the sealing resin 211 toward the area between the first bump line 204a and the first bump line 204b.

Accordingly, the fifth embodiment exhibits the same advantageous effects as the fourth embodiment.

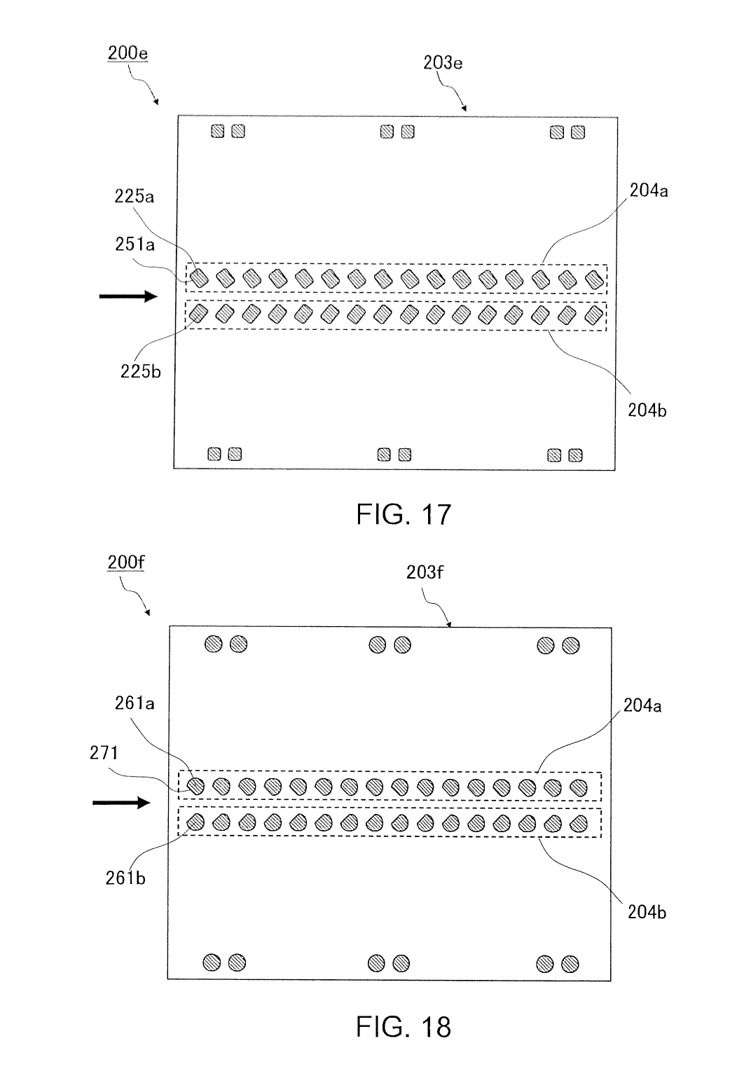

Next, a sixth embodiment of the present invention will be described with reference to FIG. 17.

In the sixth embodiment, the first bumps 225a are inclined with respect to a direction in which the first bump lines 204a and 204b extend in the first embodiment. Thus, side surfaces 251a of the first bumps 225a are used as guide portions according to the present invention.

In the sixth embodiment, components having the same functions as those in the first embodiment are denoted by the same reference numerals. Thus, the following description focuses on differences between the sixth embodiment and the first embodiment.

As shown in FIG. 17, a semiconductor device 200e according to the sixth embodiment includes a semiconductor chip 203e including first bumps 225a and 225b, which constitute first bump lines 204a and 204b. Each of the first bumps 225a and 225b is in the form of a quadrangular prism.

Each of the first bumps 225a and 225b is inclined with respect to the direction in which the first bump lines 204a and 204b extend. The side surfaces 251a of the first bumps 225a and 225b are arranged so that the intervals between those side surfaces 251a of the first bumps 225a and 225b gradually decrease from one side of the wiring board 201 toward an area between the adjacent bump lines (first bump lines 204a and 204b). Thus, the side surfaces 251a of the first bumps 225a and 225b serve as guide portions according to the present invention.

More specifically, the first bumps 225a are arranged so that the side surfaces 251a of the first bumps 225a are inclined in the same direction, and the first bumps 225b are arranged so that the side surfaces of the first bumps 225b are inclined in the same direction. The nearest pair of first bumps 225a and 225b forms an inverted-V shape. In FIG. 17, a pair of first bumps 225a and 225b opposed to each other forms an inverted-V shape.

Thus, the guide portions according to the present invention does not necessarily need to be members separated from the first bumps 225a and 225b. The guide portions can be provided by properly adjusting the shape and location of the first bumps 225a and 225b. As with the first embodiment, this configuration can prevent voids from being generated in the sealing resin 211 filling at least the gap between the wiring board 201 and the semiconductor chip 203e. Furthermore, since no through hole is formed in the wiring board 201, the sealing resin 211 does not flow onto the lands 219 formed on a rear face of the wiring board 201. Thus, the reliability of the semiconductor device 200e can be improved.

In this manner, according to the sixth embodiment, the semiconductor device 200e includes the wiring board 201, the first bump lines 204a and 204b as a plurality of bump lines arranged adjacent to each other, the semiconductor chip 203e mounted on the wiring board 201 with the first bump lines 204a and 204b interposed between the semiconductor chip 203e and the wiring board 201, the sealing resin 211 filled in the gap formed between the wiring board 201 and the semiconductor chip 203e, and the side surfaces 251a as guide portions provided between the wiring board 201 and the semiconductor chip 203e guiding the sealing resin 211 toward between the first bump line 204a and the first bump line 204b.

Accordingly, the sixth embodiment exhibits the same advantageous effects as the first embodiment.

Furthermore, according to the sixth embodiment of the present invention, the side surfaces 251a (inclination portions) as the guide portions are formed by inclining the first bumps 225a and 225b with respect to the direction in which the first bump lines 204a and 204b extend.

Therefore, unlike the first embodiment, the guide portions do not need to be provided separately from the first bump lines 204a and 204b. Accordingly, the structure of the semiconductor device can be more simplified.

Next, a seventh embodiment of the present invention will be described with reference to FIG. 18.

In the seventh embodiment, cylindrical bumps are used for the first bumps 225b of the sixth embodiment. A side surface of each of the cylindrical bumps is cut to form a tapered portion 271 such that the tapered portion 271 is inclined with respect to a direction in which the first bump lines 204a and 204b extend. Thus, the tapered portions 271 of the first bumps 225b are used as guide portions according to the present invention.

In the seventh embodiment, components having the same functions as those in the sixth embodiment are denoted by the same reference numerals. Thus, the following description focuses on differences between the seventh embodiment and the sixth embodiment.

As shown in FIG. 18, a semiconductor device 200f according to the sixth embodiment includes a semiconductor chip 203f including first bumps 261a and 261b, which constitute first bump lines 204a and 204b. Each of the first bumps 261a and 261b is in the form of a cylinder.

Each of the first bumps 261a and 261b has such a shape that part of a side surface is cut and inclined with respect to the direction in which the first bump lines 204a and 204b extend. The cut portion forms a tapered planar portion 271 (guide portion). The tapered portions 271 of the first bumps 204a and 204b are formed so that the intervals between those tapered portions 271 of the first bumps 204a and 204b gradually decrease from one side of the wiring board 201 that is opposed to a direction in which the sealing resin 211 is filled, toward an area between the first bump lines 204a and 204b.

More specifically, the first bumps 261a are arranged so that the tapered portions 271 of the first bumps 261a are inclined in the same direction, and the first bumps 261b are arranged so that the tapered portions of the first bumps 261b are inclined in the same direction. The nearest pair of first bumps 261a and 261b forms an inverted-V shape. In FIG. 18, a pair of first bumps 261a and 261b opposed to each other forms an inverted-V shape.

Thus, the guide portions according to the present invention can be provided by forming the tapered planar portions 271 on the first bumps, rather than by arranging the first bumps in an inclined manner. As with the first embodiment, this configuration can prevent voids from being generated in the sealing resin 211 filling at least the gap between the wiring board 201 and the semiconductor chip 203f. Furthermore, since no through hole is formed in the wiring board 201, the sealing resin 211 does not flow onto the lands 219 formed on a rear face of the wiring board 201. Thus, the reliability of the semiconductor device 200f can be improved.

In this manner, according to the seventh embodiment, the semiconductor device 200f includes the wiring board 201, the first bump lines 204a and 204b as a plurality of bump lines arranged adjacent to each other, the semiconductor chip 203f mounted on the wiring board 201 with the first bump lines 204a and 204b interposed between the semiconductor chip 203f and the wiring board 201, the sealing resin 211 filled in the gap formed between the wiring board 201 and the semiconductor chip 203f, and the tapered portion 271 as guide portions provided between the wiring board 201 and the semiconductor chip 203f guiding the sealing resin 211 toward the area between the first bump line 204a and the first bump line 204b.

Accordingly, the seventh embodiment exhibits the same advantageous effects as the sixth embodiment.

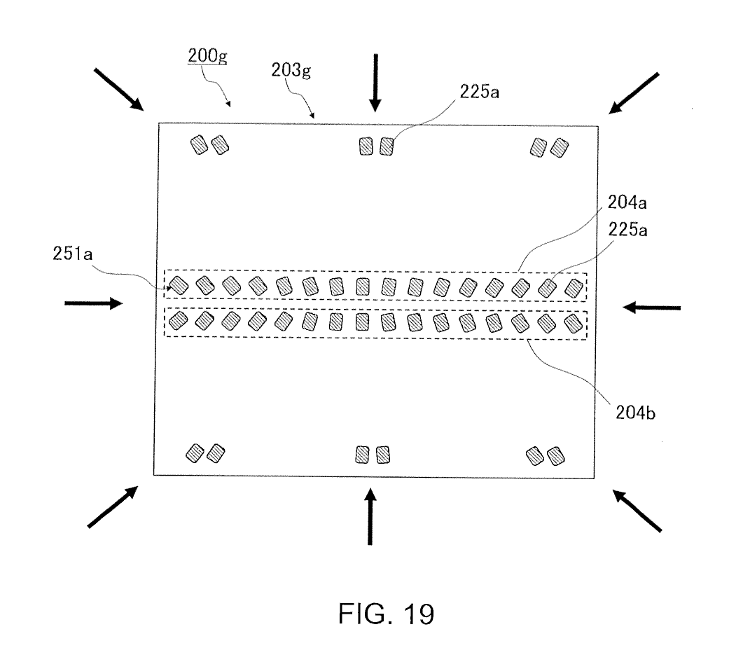

Next, an eighth embodiment of the present invention will be described with reference to FIG. 19.

In the eighth embodiment, first bumps 225a and 225b in the form of a quadrangular prism are radially arranged so that the intervals between side surfaces of the first bumps 225a and 225b gradually decrease in a plurality of filling directions toward an area between the two bump lines (first bump lines 204a and 204b) of the sixth embodiment.

In the eighth embodiment, components having the same functions as those in the sixth embodiment are denoted by the same reference numerals. Thus, the following description focuses on differences between the eighth embodiment and the sixth embodiment.

As shown in FIG. 19, a semiconductor device 200g according to the sixth embodiment includes a semiconductor chip 203g including first bump lines 204a and 204b including first bumps 225a and 225b in the form of a quadrangular prism. The first bumps 225a and 225b are radially arranged so that the intervals between side surfaces 251a of the first bumps 225a and 225b gradually decrease in a plurality of filling directions, as indicated by arrows in FIG. 19, toward an area between the first bump lines 204a and 204b.

Thus, the side surfaces 251a of the first bumps 225a and 225b may not necessarily be oriented in one direction and may be oriented in a plurality of directions corresponding to the filling directions.

With this configuration, the present invention can be applied to a case where a resin molding is conducted by a compression molding process.

Specifically, a sealing resin flows into between the wiring board 201 and the semiconductor chip 203g in all directions when a compression molding process is used. Since the first bumps 225a and 225b in the form of a quadrangular prism are radially arranged, the sealing resin that flow in any direction can be guided by those first bumps 225a and 225b.

In this manner, according to the eighth embodiment, the semiconductor device 200g includes the wiring board 201, the first bump lines 204a and 204b as a plurality of bump lines arranged adjacent to each other, the semiconductor chip 203g mounted on the wiring board 201 with the first bump lines 204a and 204b interposed between the semiconductor chip 203g and the wiring board 201, the sealing resin 211 filled in the gap formed between the wiring board 201 and the semiconductor chip 203g, and the side surfaces 251a as guide portions provided between the wiring board 201 and the semiconductor chip 203g guiding the sealing resin 211 toward the area between the first bump line 204a and the first bump line 204b.

Accordingly, the eighth embodiment exhibits the same advantageous effects as the sixth embodiment.

Although the inventions has been described above in connection with several preferred embodiments thereof, it will be appreciated by those skilled in the art that those embodiments are provided solely for illustrating the invention, and should not be relied upon to construe the appended claims in a limiting sense.

For example, in the above embodiments, the present invention has been described with examples where two lines of bump electrodes are formed at a central area of the semiconductor chip 203. Nevertheless, the present invention is not limited to such examples. The present invention is applicable to any structure including a plurality of bump lines arranged adjacent to each other.

What is claimed is:

1. A semiconductor device comprising:
a wiring board;
a semiconductor chip including a plurality of bump lines arranged adjacent to each other on a surface of the semiconductor chip, the semiconductor chip being mounted on the wiring board while the plurality of bump lines are interposed between the semiconductor chip and the wiring board;
a sealing resin filled in at least a gap between the wiring board and the semiconductor chip; and
a guide portion provided between the wiring board and the semiconductor chip guiding the sealing resin toward an area between the adjacent bump lines.

2. The semiconductor device as recited in claim 1, wherein the guide portion comprises guide bump lines arranged on the surface of the semiconductor chip so that intervals between the guide bump lines decrease from one side of the wiring board toward the area between the adjacent bump lines.

3. The semiconductor device as recited in claim 2, wherein the guide bump lines are arranged near ends of the adjacent bump lines.

4. The semiconductor device as recited in claim 2, wherein the guide bump lines are arranged between ends of the plurality of bump lines.

5. The semiconductor device as recited in claim 2, wherein the guide bump lines are arranged between ends of the plurality of bump lines so as to cross a direction in which the adjacent bump lines extend.

6. The semiconductor device as recited in claim 1, wherein the guide portion comprises a concave tapered portion provided on a surface of the wiring board on which the semiconductor chip is mounted so that a width of the concave tapered portion decreases from one side of the wiring board toward the area between the adjacent bump lines.

7. The semiconductor device as recited in claim 1, further comprising:
a solder resist provided on the wiring board,
wherein the guide portion comprises a protrusion provided on the solder resist.

8. The semiconductor device as recited in claim 1, wherein the guide portion comprises inclination portions each provided on a side surface of a bump of the plurality of bump lines that is opposed to another bump of the plurality of bump lines so that intervals between the side surfaces of the bumps decrease from one side of the wiring board toward the area between the adjacent bump lines.

9. The semiconductor device as recited in claim 8, wherein the inclination portions are formed by arranging the bumps at an angle with respect to a direction in which the plurality of bump lines extend.

10. The semiconductor device as recited in claim 9, wherein the inclination portions comprise tapered portions formed on side surfaces of the bumps.

11. A semiconductor device comprising:
a semiconductor chip including a plurality of bump lines arranged adjacent to each other on a surface of the semiconductor chip, the semiconductor chip being mounted on a wiring board while the plurality of bump lines are interposed between the semiconductor chip and the wiring board; and
a guide portion guiding a sealing resin to be formed on the surface of the semiconductor chip toward an area between the adjacent bump lines.

12. The semiconductor device as recited in claim 11, wherein the guide portion comprises guide bump lines arranged on the surface of the semiconductor chip so that intervals between guide bumps of the guide bump lines decrease from one side of the wiring board toward the area between the adjacent bump lines.

13. The semiconductor device as recited in claim 12, wherein the guide bump lines are arranged near ends of the adjacent bump lines.

14. The semiconductor device as recited in claim 12, wherein the guide bump lines are arranged between ends of the plurality of bump lines.

15. The semiconductor device as recited in claim 12, wherein the guide bump lines are arranged between ends of the plurality of bump lines so as to cross a direction in which the adjacent bump lines extend.

16. The semiconductor device as recited in claim 11, wherein the guide portion comprises inclination portions each provided on a side surface of a bump of the plurality of bump lines that is opposed to another bump of the plurality of bump lines so that intervals between the side surfaces of the bumps decrease from one side of the wiring board toward the area between the adjacent bump lines.

17. The semiconductor device as recited in claim 16, wherein the inclination portions are formed by arranging the bumps at an angle with respect to a direction in which the plurality of bump lines extend.

18. A semiconductor device comprising:
a wiring substrate including an upper surface thereof;
a semiconductor chip including a first surface, a plurality of first bump electrodes arranged along a first line on the first surface and a plurality of second bump electrodes arranged along a second line on the first surface, the second line being arranged in parallel with the first line and adjacent to the first line, the semiconductor chip being mounted over the upper surface of the wiring substrate so that the first and second bump electrodes interpose between the wiring substrate and the semiconductor chip; and
a sealing resin filled in a gap between the wiring substrate and the semiconductor chip,
wherein the wiring substrate includes a guide portion formed on the upper surface thereof, the guide portion is uneven with respect to a remaining portion of the upper surface, and the guide portion is extended from an area between the first and second lines toward a peripheral edge of the wiring substrate.

19. The semiconductor device as recited in claim 18, wherein the guide portion is extended from the area between the first and second lines toward the peripheral edge of the wiring substrate, and a width of the guide portion increases toward the peripheral edge.

20. The semiconductor device as recited in claim 18, wherein the guide portion comprises a concave portion on the upper surface of the wiring substrate, the concave portion is smaller in thickness than the remaining portion.
